(19) United States
(12) Patent Application Publication
(10) Pub. No.: US 2016/0345441 A1
(43) Pub. Date: Nov. 24, 2016

(54) VERIFYING COMPONENTS FOR PLACEMENT

(71) Applicant: Accu-Assembly Incorporated, Andover, MA (US)

(72) Inventor: Yuen-Foo Michael Kou, Andover, MA (US)

(21) Appl. No.: 14/720,295

(22) Filed: May 22, 2015

(51) Int. Cl. H05K 3/30; H05K 13/02; H05K 13/04; B65H 5/28

(52) U.S. Cl. CPC H05K 3/30; B65H 5/28; H05K 13/02; H05K 13/04; H05K 2203/0147

(57) ABSTRACT

An electronic component sequencing and insertion machine includes a set of component tape carrier holders each configured to receive a respective carrier containing a length of tape holding leads of a series of electronic components in spaced relation along the tape, and a set of component dispensers for sequentially dispensing individual electronic components for insertion into a printed circuit board, each component dispenser arranged to receive a corresponding tape from a corresponding one of the tape carrier holders, each component dispenser having an exposed input slot for threading a free end of the tape into the component dispenser at machine setup. Each component dispenser includes a tape color sensor downstream of the input slot, for verifying by tape color a polarity of components held by the tape as threaded into the component dispenser.

### TECHNICAL FIELD

This disclosure relates to verifying components for placement, and more particularly to verifying polarity of electronic components and/or splice connection of carrier tapes in electronic component placement machines, e.g., sequencing and insertion machines.

### BACKGROUND

Electronic components can be supplied to component placement machines on carrier tapes spooled onto reels for removal by a pickup member and subsequent placement onto a destination circuit board. For example, in sequencing and insertion machines, tape mounted electronic components are transported over chains to dispensers and picked up by insertion mechanism which trims, forms, and inserts the component leads into holes of a circuit board. In some cases, a wrong electronic component is loaded to a dispenser or an electronic component is loaded wrongly, e.g., in reversed polarity, which may cause severe problems to the assembled circuit board.

### SUMMARY

One aspect of the subject matter described in this specification features an electronic component placement machine comprising a set of component tape carrier holders each configured to receive a respective carrier containing a length of tape holding leads of a series of electronic components in spaced relation along the tape; and a set of component dispensers for sequentially dispensing individual electronic components for insertion into a printed circuit board, each component dispenser arranged to receive a corresponding tape from a corresponding one of the tape carrier holders, each component dispenser having an exposed input slot for threading a free end of the tape into the component dispenser at machine setup. Each component dispenser comprises a tape color sensor downstream of the input slot, for verifying by tape color a polarity of components held by the tape as threaded into the component dispenser.

The tape color sensor can be configured to direct a light toward a side of the tape downstream from the input slot and generate a signal indicative of a reflection of the directed light. In some implementations, the machine further includes a processor coupled to the tape color sensor, the processor including executable instructions to receive a signal from the tape color sensor, and to verify a polarity of components held by the tape as a function of the received signal. The processor can be configured to verify the polarity by comparing the received signal to a reference associated with an expected signal corresponding to a correct component polarity. The processor can be further configured to send an alert signal in response to determining that a difference between the received signal and the reference is above a predetermined threshold.

In some examples, the tape color sensor is a first tape color sensor. Each component dispenser can further include a second tape color sensor, and the first and second tape color sensors are positioned on opposite sides of a gap through which the tape passes and are configured to generate separate signals corresponding to color of opposite sides of the tape. The first tape color sensor is integrated into a first electronic board and the second tape color sensor is integrated into a second electronic board, the first and second electronic boards positioned on opposite sides of the gap and electrically coupled.

Each component dispenser can include a removable bracket mounted to a frame of the component dispenser, defining the input slot and configured to hold the tape color sensor. Each component dispenser can also include two input slots aligned across a gap and spaced to receive parallel tapes holding opposite ends of electronic components.

In some implementations, each component dispenser further includes a splice sensor responsive to a splice connector connecting two sequential lengths of tape. The splice sensor and tape color sensor can be both integrated into a single electronic board. The splice sensor can be also coupled to a processor configured to receive a signal from the splice sensor indicating detection of a splice connector. The processor can be further configured to alert an operator in response to receiving the signal from the splice detector at a time not associated with a tape position corresponding to a previously noted splice. In some examples, the splice sensor is responsive to metal splice connectors. In some examples, the splice sensor is responsive to a change in color associated with a splice connection.

Another aspect of the subject matter described in this specification features a method comprising: installing on a circuit board assembly machine a carrier containing a length of tape holding a series of axial lead electronic components in spaced relation along the tape; threading the tape into an exposed input slot of a component dispenser of the machine, the component dispenser comprising a tape color sensor downstream of the input slot; and running the machine to assemble circuit boards with components dispensed from the component dispenser, while the machine verifies by tape color a polarity of components held by the tape as threaded into the component dispenser.

In some implementations, the component dispenser further comprises a splice sensor responsive to a splice connector connecting two sequential lengths of tape, and wherein running the machine comprises running the machine while the machine monitors for splice connectors at the component dispenser.

Particular embodiments of the subject matter described in this specification can be implemented so as to realize one or more of the following advantages. An electronic component placement machine including a tape color sensor can verify by tape color a polarity of a series of components held by the tape as threaded into a dispenser. The tape color sensor verifies the polarity of components as threaded into the dispenser, which can help to identify threading errors before components are incorrectly inserted onto a circuit board. The electronic component placement machine can include a splice sensor to detect splice connectors connecting two sequential lengths of tape, which can be used to identify wrong tape connection, monitor reel count, and reset component count. The tape color sensor and/or the splice sensor may be integrated into an electronic board that is simple, inexpensive, easy to install and maintain, and easily adopted to existing component placement machines, e.g., axial-lead component sequencing and insertion machines, radial-lead component sequencing and insertion machines, or surface mount machines.

The details of one or more implementations of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A is a perspective view of an example electronic component sequencing and insertion machine.

FIG. 1B is a schematic diagram of a system configuration of the example machine of FIG. 1A.

FIG. 2A is a perspective view of an example electronic component sequencing and insertion machine including dispensers and associated sensing mechanism.

FIG. 2B is an enlarged view of a part of FIG. 2A.

FIG. 3A is a perspective view of an example dispenser with a sensing mechanism and tape mounted electronic components.

FIG. 3B is a perspective view of the example dispenser with the sensing mechanism of FIG. 3A.

FIG. 4 is a perspective view of example carrier tapes with splice connectors.

FIG. 5A is a perspective view of an example sensing mechanism.

FIG. 5B is a perspective view of an example electronic board integrated with a tape color sensor and a splice sensor of the sensing mechanism of FIG. 5A.

FIG. 5C is a schematic view of the sensing mechanism of FIG. 5A with a threaded tape.

FIG. 6A is a perspective view of a radial-lead component sequencing and insertion machine.

FIG. 6B is a schematic view of a carrier tape with two-pin radial-lead components.

FIG. 6C is a schematic view of a carrier tape with three-pin radial-lead components.

FIG. 7 is a flowchart of an example process according to an example embodiment of the disclosure.

Like reference numbers and designations in the various drawings indicate like elements.

### DETAILED DESCRIPTION

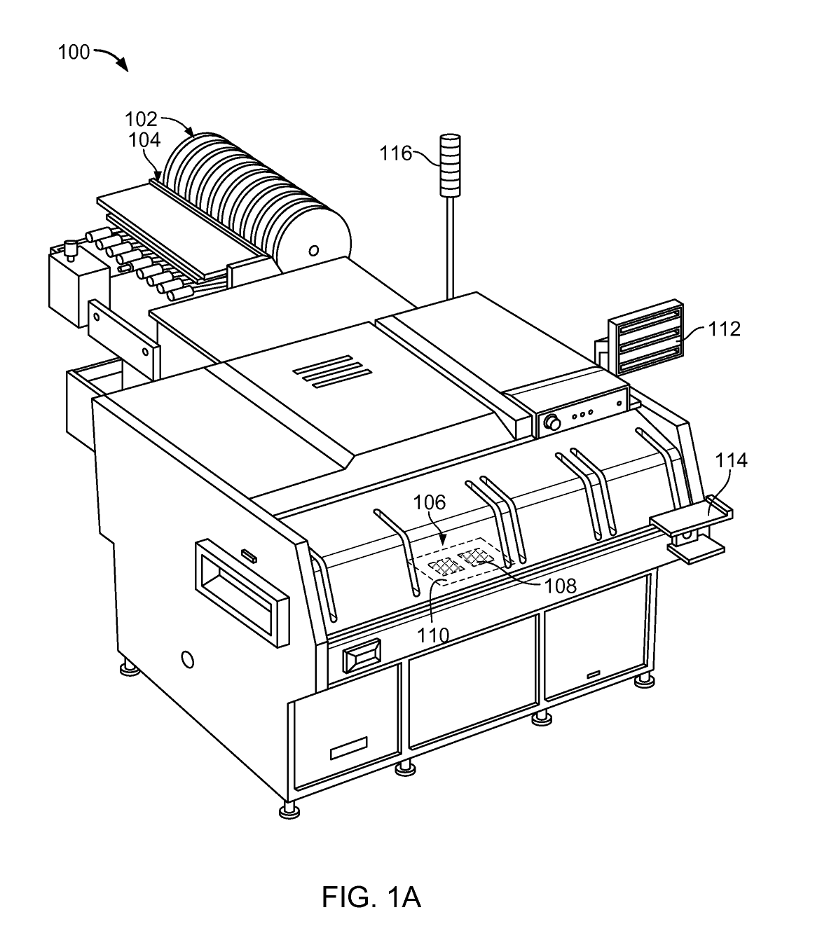

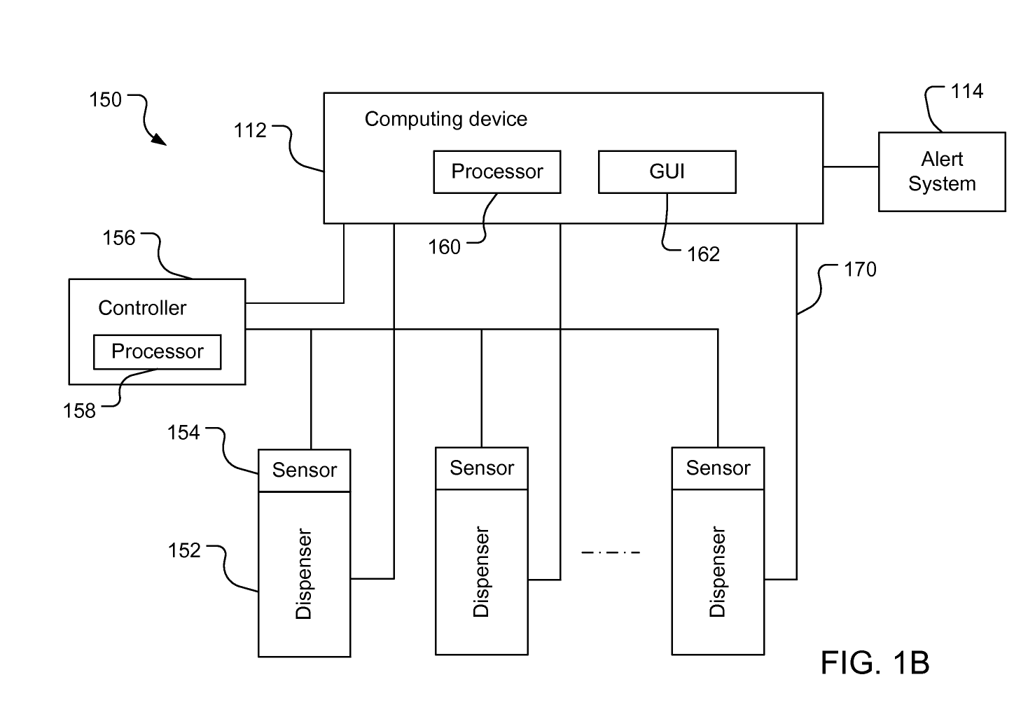

FIG. 1A shows an electronic component placement machine 100 according to an embodiment of the disclosure. It should be understood that while machine 100 is illustrated as an axial-lead component sequencing and insertion machine, details of the description below may be employed in any setting or application requiring verification of the polarity of electronic components and/or splice connection of carrier tapes. Such a setting or application can include, for example, radial-lead component sequencing and insertion machines and/or surface mounted machines, to name a few.

Electronic component placement machine 100 includes a series of electronic component carriers 102 positioned within corresponding component carrier tape holders 104, e.g., feeder slots. Each carrier 102 can receive a reel containing a length of component carrier tape holding leads of a series of electronic components in spaced relation along the tape. Each component tape carrier holder 104 receives a respective carrier 102. From the carriers, the tapes are transported to corresponding dispensers in a dispensing area 106. The dispensers receive the selected component carrier tapes and provide the electronic components in a predetermined sequence to an insertion assembly which trims, forms, and inserts the component leads into holes of individual circuit boards 108. The electronic component placement machine 100 also includes a circuit board positioning mechanism 110, which moves individual circuit boards 108 in turn under the insertion assembly for component insertion.

Electronic component placement machine 100 includes a computing device 112 for controlling the machine 100 and/or processing, storing and displaying various data related to the machine 100. The computing device 112 can communicate with the machine 100 and with a component inventory database program, and can update the current status of the components on the machine 100. The computing device 112 can include any appropriate type of device such as a desktop computer, a tablet computing device, a mobile communication device, a handheld computer, a personal digital assistant (PDA), a network appliance, a mobile phone, or any appropriate combination of any two or more of these data processing devices or other data processing devices. The computing device 112 can include one or more machine-readable repositories, or databases.

A data entry device 114, e.g., a keyboard and/or a mouse, is coupled to the computing device 112 to enable a machine operator to enter various data associated with reels and circuit boards that are processed by machine 100, and to operate machine 100, e.g., to start, pause, or stop machine 100. Machine 100 also includes an alert system 116. The computing device 112 or other computing devices can activate the alert system 116 to alert the operator in the case of an emergency or an operational error, e.g., when an electronic component is loaded with a reversed polarity, when a wrong electronic component is loaded, or when an inventory of remaining components runs out. This alert may include, for example, activating an audible or visual alarm, displaying an alert signal on a display screen of the computing device 112, or perhaps even de-energizing machine 100.

FIG. 1B shows a schematic diagram of a system configuration 150 of electronic component placement machine 100. The computing device 112 includes a processor 160 and a graphic user interface (GUI) 162. A number of dispensers 152 in the dispensing area 104 are each individually connected to the computing device 112 and communicate with the computing device 112 via a physically hardwired connection 170. In some implementations, the dispensers 152 communicate with the computing device 112 via a network. The network can be a wired connection or a wireless network, which can include a computer network, such as a local area network (LAN), the Internet, or a combination thereof connecting any number of computing devices and server systems. The alert system 114 can also be connected to and communicate with the computing device 112 via a hardwired connection or the network.

Each dispenser 152 includes a respective sensing mechanism 154. The sensing mechanism 154 can be removably mounted on a standard tape dispenser, or can be an integral part of the dispenser 152 as manufactured. As discussed in further details below, the sensing mechanism 154 includes a tape color sensor configured to verify by tape color a polarity of components held by a tape threaded into the dispenser 152. For example, the tape can have different colors on each side of an electronic component, e.g., anode side or cathode side. The tape color sensor can be programmed to select for detection a color on a side, e.g., anode side or cathode side, and determine whether the polarity is correct by detecting whether or not the color is present. If a detected color is not the selected color on the side, the tape color sensor then determines that the polarity is wrong. In some implementations, the sensing mechanism 154 includes a splice sensor configured to detect a splice connector connecting two sequential lengths of tape.

A controller 156 is configured to communicate to one or more sensing mechanism 154 for the dispensers 152. The controller 156 can include a processor 158, e.g., a microprocessor (MCU), to collect sensor data from the sensing mechanism 154 and/or process the sensor data. The controller 156 can further communicate the sensor data to a control computer. The control computer can process the sensor data to determine whether there is any operation error. In response to determining that there is an operation error, the control computer can activate the alert system 114, e.g., by sending a trigger signal to the alert system 114. In some implementations, the computing device 112 includes the control computer. In some other implementations, the control computer is remote from the computing device 112.

Electronic component placement machine 100 can include a number of controllers 156 that each communicate to one or more sensing mechanisms 154. For example, suppose that machine 100 includes forty dispensers and each controller 156 is configured to communicate with ten sensing mechanisms 154, machine 100 can then include four controllers 156 for forty sensing mechanisms 154 locally coupled to the forty dispensers 152. The controllers 156 can be serially connected to the control computer.

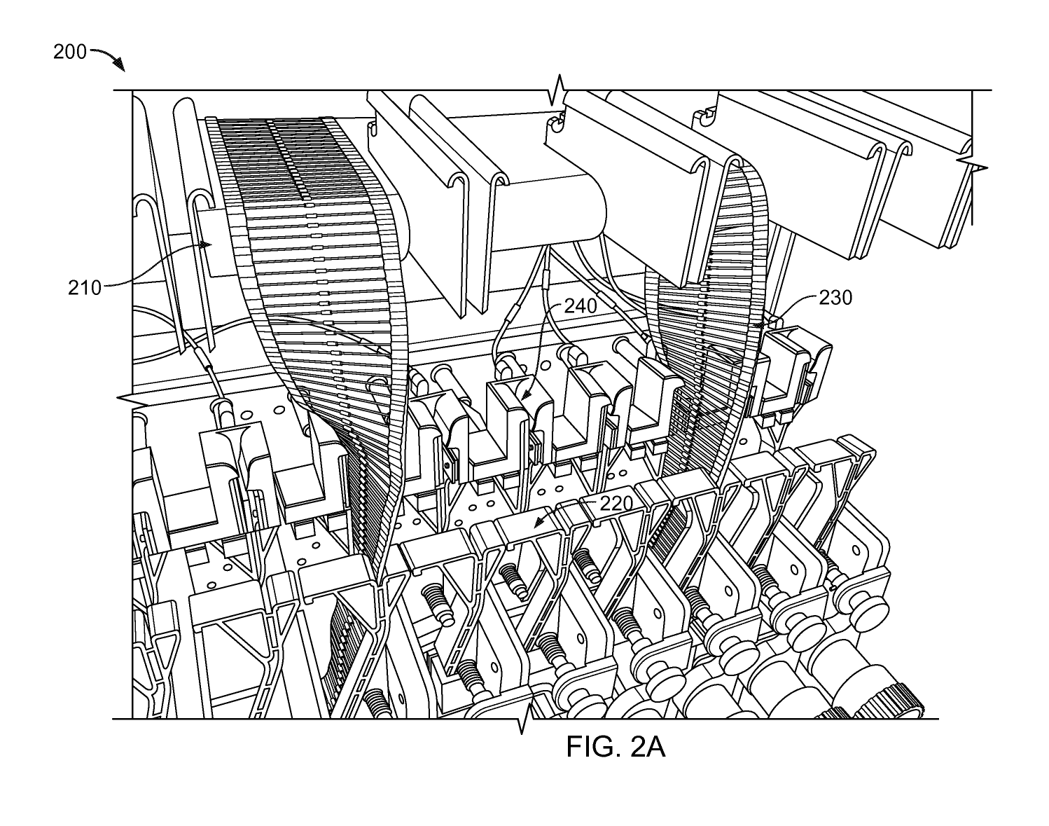

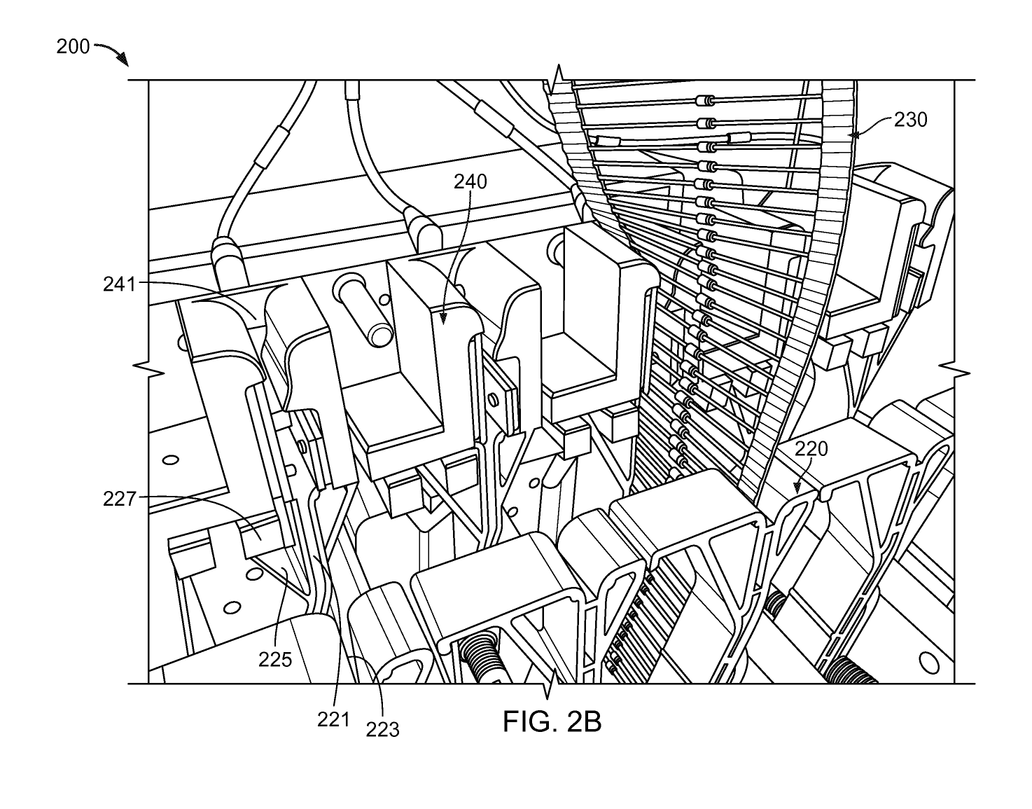

FIGS. 2A and 2B show an example electronic component sequencing and insertion machine 200 including dispensers 220 and associated sensing mechanisms 240. Machine 200 includes a set of component tape carrier holders, e.g., the component tape carrier holder 104 of FIG. 1A. Each holder receives a respective carrier containing a length of tape 230 holding leads of a series of electronic components in spaced relation along the tape. Machine 200 also includes a set of component dispensers 220 for sequentially dispensing individual electronic components for insertion into a printed circuit board.

Machine 200 includes a set of channels 210 each defined by a shelf 212 shielded by two vertical plates 214. Each component dispenser 220 is arranged to receive a corresponding tape 230 from a corresponding one of the tape carrier holders over a corresponding channel 210. In some implementations, the component dispenser 220 is positioned below the corresponding channel 210. The dispenser 220 defines two input slots 221 and 223 aligned across a gap and spaced to receive parallel tapes holding opposite ends of the electronic components. The input slots 221 and 223 are aligned along a direction perpendicular to a feeding direction of the carrier taps 230 from the channel 210, such that the carrier tapes 230 are rotated about 90 degree into the dispenser 220, with a series of electronic components spaced vertically along the tape.

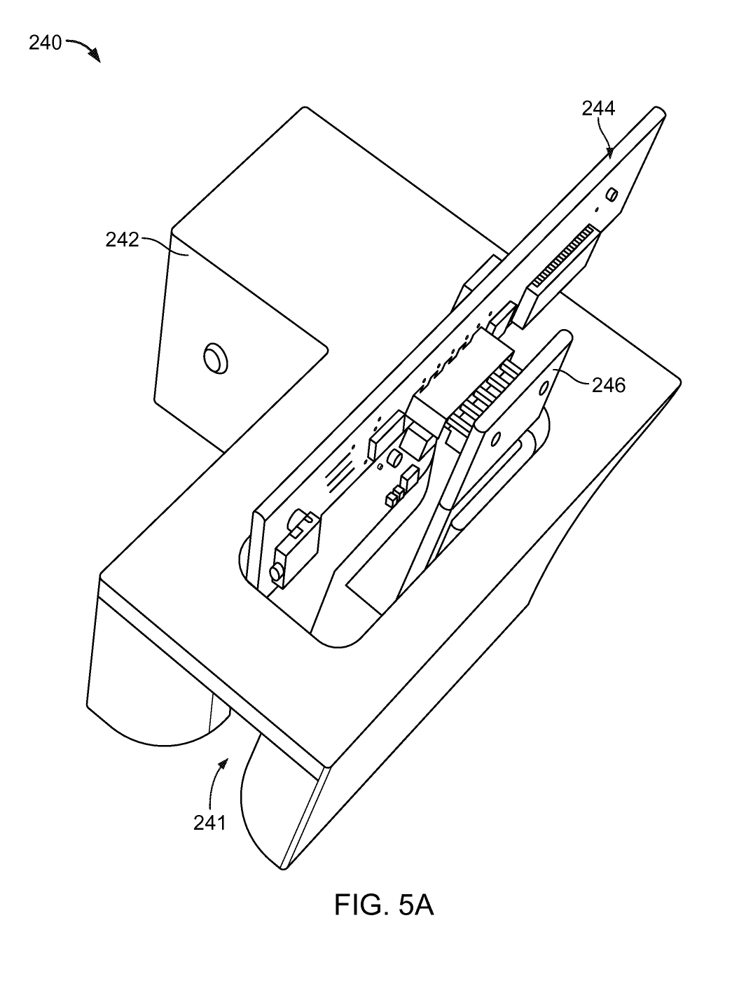

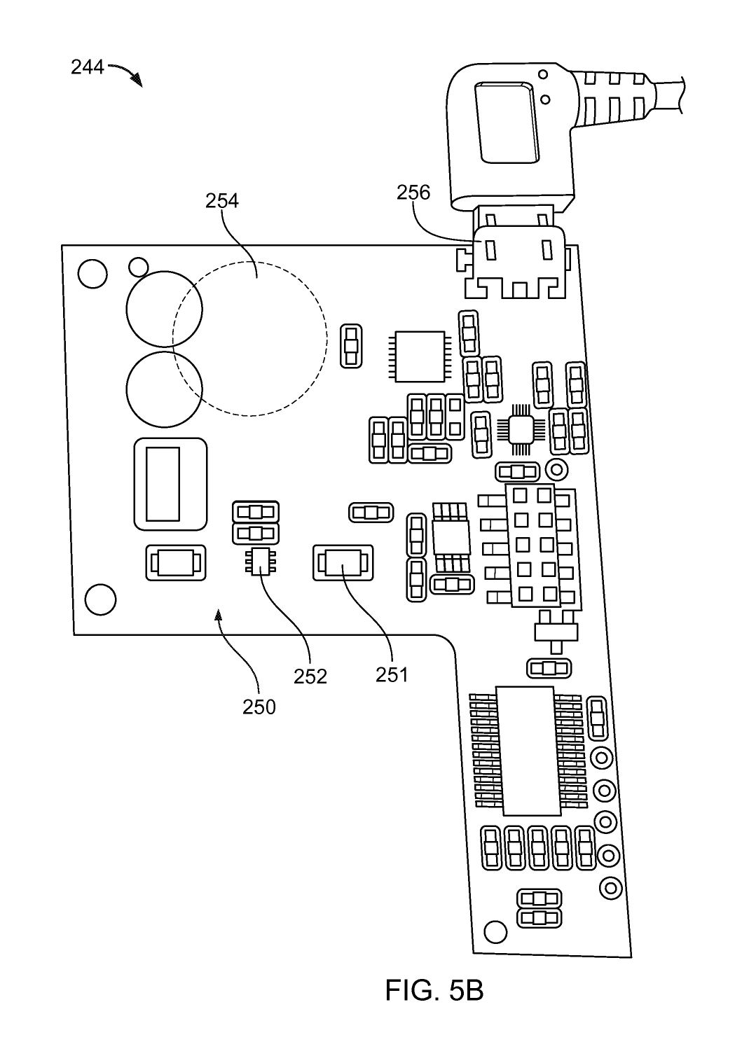

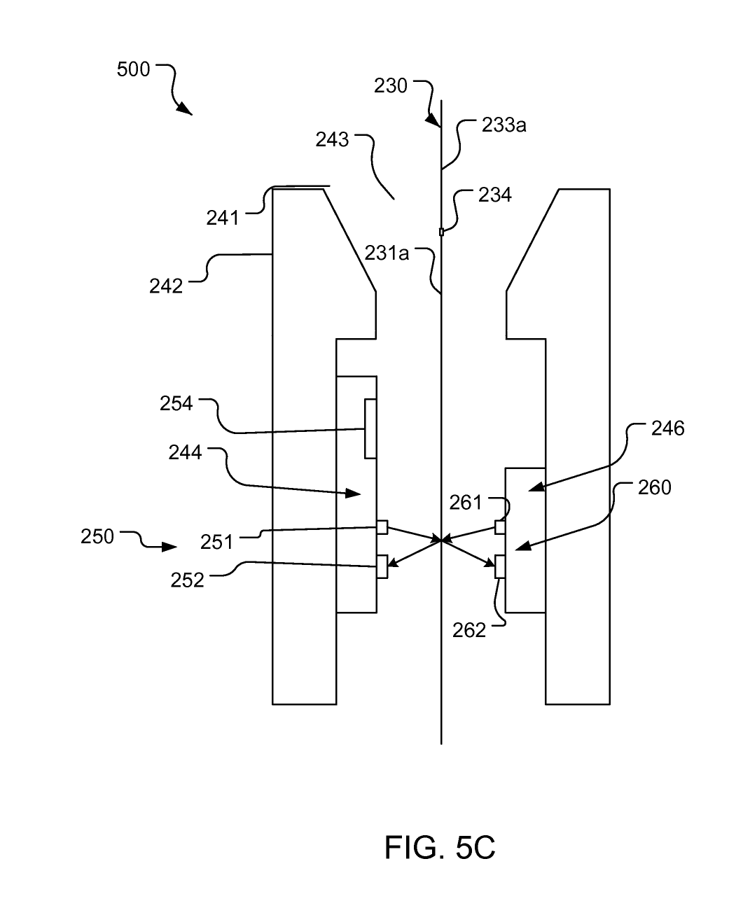

Each dispenser 220 includes a sensing mechanism 240 that can be on the top of the dispenser 220. The sensing mechanism 240 can be removably mounted on the dispenser or can be an integral part of the dispenser as manufactured. The sensing mechanism 240 defines an input slot 241 that is aligned with the input slot 221 of the dispenser 220, such that the carrier tape 230 is threaded through input slot 241 and downstream to input slot 221. As discussed in further details in FIGS. 5A-5C, the sensing mechanism 240 includes a tape color sensor and/or a splice sensor, e.g., integrated into an electronic board, positioned to be adjacent a side of the threaded carrier tape 230. The tape color sensor and/or the splice sensor are positioned below the entrance to input slot 241 but above input slot 221, such that the tape color sensor and/or the splice sensor can detect tape color and/or splice connection when the carrier tape 230 is threaded into the dispenser 220.

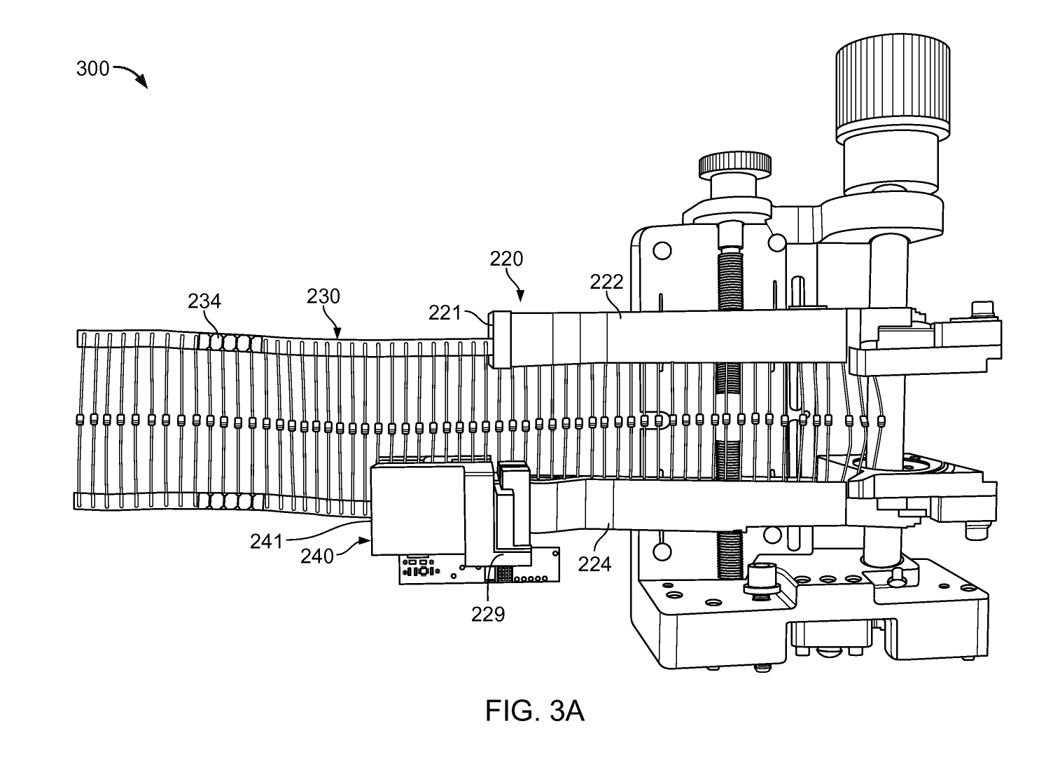

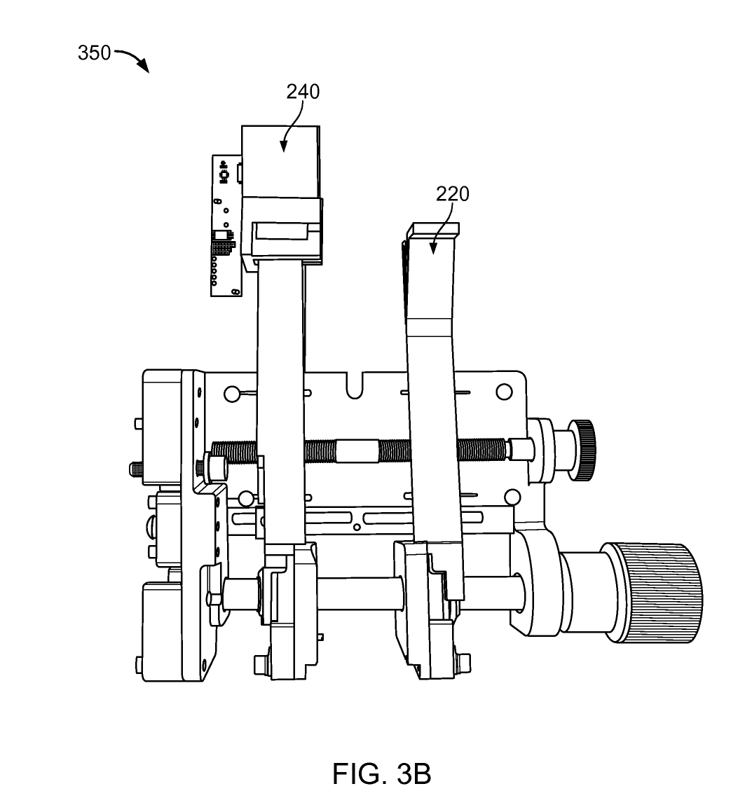

FIGS. 3A and 3B show a dispenser 220 assembled with the sensing mechanism 240 threaded with a carrier tape 230 holding axial-lead electronic components (FIG. 3A), and without the carrier tape 230 (FIG. 3B), respectively. The dispenser 220 includes two parallel frame parts 222 and 224 spaced by a gap. Frame parts 222 and 224 define input slot 221 and input slot 223, respectively.

Frame part 222 defines a cavity 225 (as shown in FIG. 2B) extending along a longitudinal direction of input slot 221. The sensing mechanism 240 includes a support arm 227 (as shown in FIG. 2B) sized to be inserted into the cavity 225 of frame part 222. The sensing mechanism 240 also defines a slot 229 perpendicular to input slot 241. A top of frame part 222 can be inserted into the slot 229 such that the sensing mechanism 240 can be held on top of the dispenser 220.

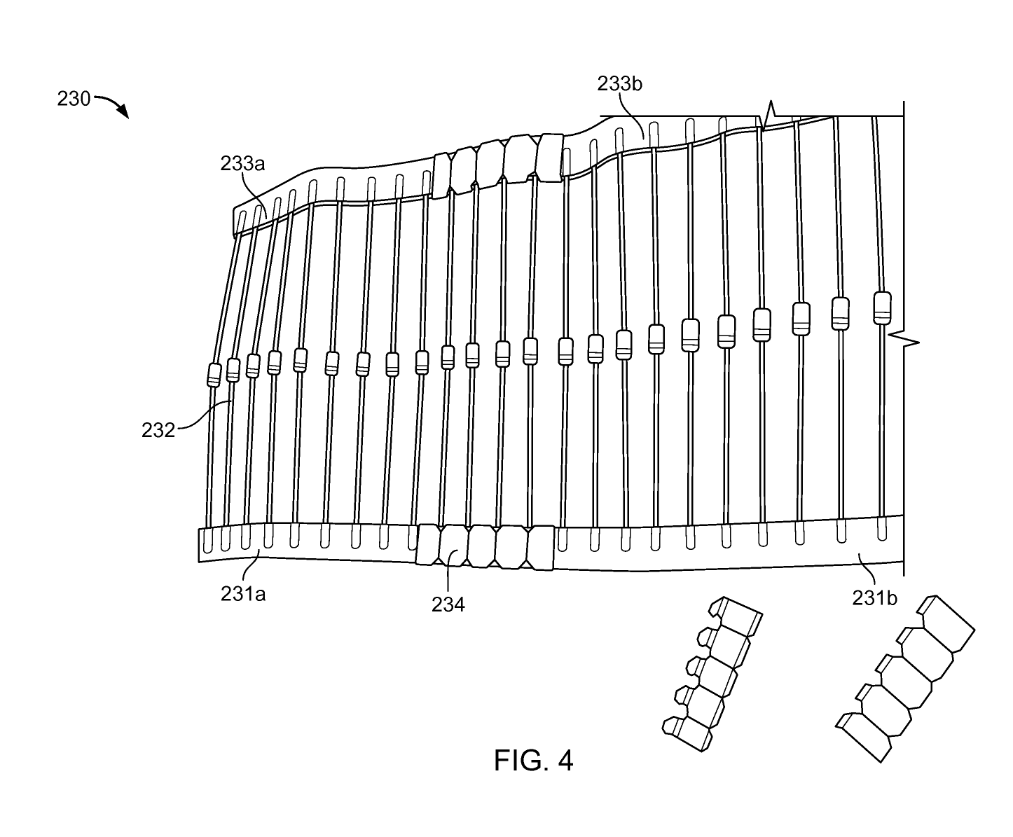

FIG. 4 shows a perspective view of carrier tape 230. Each axial-lead electronic component 232 has leads extending from two opposite ends, that is, a negative lead and a positive lead, or an anode end and a cathode end. A component reel can include a cover tape that overlays a series of components 232 in spaced relation along the tape and is peeled away from the carrier tape before components 232 are picked from the carrier tape for assembly onto boards. In some cases, two cover tapes are used to hold two ends of each electronic component 232.

To mark a polarity of the component 232, the ends of each component 232 are attached to two different color tapes 231a and 233a, respectively. For example, the cathode end of the component is attached to color tape 231a with a color of red, and the anode end of the component is attached to color tape 233a with a color of white. Therefore, by verifying the tape color, the polarity of the component can be determined. Colors of tapes 231a and 233a can be red and white, red and blue, red and green, blue and green, blue and white, or any visually distinguishable color combination. In some implementations, only one end of the component 232 is attached to a color tape. The other end of the component 232 can be attached to a transparent tape or without tape. Associations between polarity of electronic components and colors of color tapes can be stored in a database of a control computer.

Each carrier tape 231a and 233a has a length to hold a number of electronic components. For example, the carrier tape 231 a can be one meter long with 100 electronic components spaced along the length. Each carrier tape 231a or 233a can be connected to a leading end of another carrier tape 231b or 233b holding electronic components 232, e.g., a same component type, via a splice connector 234, to produce component tapes of any desired length. The splice connector 234 can be used to connect two sequential carrier tapes or two reels of carrier tapes. In some cases, when the available inventory on a reel of component tape at a particular feeder is nearly exhausted, a machine operator can splice a leading end of a new component tape to the trailing end of the nearly exhausted tape, so that the machine will not run out of inventory and will continue to operate without interruption.

The splice connector 234 can include adhesive material, e.g., an adhesive tape, metal material, or any material suitable for splicing component carrier tape. A corresponding splice sensor can include a sensing element that is responsive to a particular property associated with splicing material, for example, a particular color, reflectivity, fluorescence or magnetic property. For illustration, FIG. 4 shows a metal splice connector 234. In this particular example, the metal splice connector 234 is a copper staple. The splice sensor can be an inductive sensor to detect the metal splice connector 234. The metal splice connector 234 can extend substantially around a perimeter of the component carrier tape at discrete splice locations. The metal splice connector 234 can have a length extending along the carrier tape and across pieces of electronic components 232, e.g., 4 or 5 electronic components. By detecting splice connectors, data associated with the connected tape or reel, e.g., component count used or remaining in the connected tape, reel count used or remaining in the connected reel, can be obtained.

FIG. 5A shows an example sensing mechanism 240. The sensing mechanism 240 includes a bracket 242 that defines input slot 241. The bracket 242 can be removably mounted on a dispenser, e.g., the dispenser 220 shown in other figures, or be an integral part of the dispenser as manufactured. An electronic board 244 is held by the bracket 242.

FIG. 5B shows a view of the electronic board 244. The sensing mechanism 240 includes a tape color sensor 250 and a splice sensor 254 that are integrated into the single electronic board 244. The rest of the electronic board 244 is populated with peripheral components to support sensors 250 and 254. The electronic board 244 is positioned in the bracket 242 such that sensors 250 and 254 face a side of a carrier tape when threaded into input slot 241.

This particular tape color sensor 250 includes two light sources 251 and a detector 252. Each light source 251 can be an LED (light-emitting diode), e.g., product No. 158302260 from Wurth Electronics Inc., Minnesota. The LED can emit white light or any suitable color of light. The light sources 251 can be positioned and oriented on the electronic board 244, such that the light from the LED shines directly onto a side of the carrier tape downstream from the input slot 241. In this example, the light sources 251 are surface mounted on the electronic board 244. The tape color sensor 250 is configured such that light from each light source 251 is directed toward the side of the carrier tape and a reflection of the directed light from the side of the carrier tape is detected by the detector 252. In other examples, the tape color sensor 250 includes only one, or more than two, light sources positioned around the detector 252 such that light from each light source is reflected by the side of the carrier tape back to the detector 252.

In this example, the light sources 251 emit white light. If the side of the carrier tape is white, the reflected light from the side of the carrier tape is white. If the side of the carrier tape is red, the reflected light is red. If the side of the carrier tape is blue, the reflected light is blue. Therefore, the color of the side of the carrier tape can be determined by verifying the color of the reflected light from the side of the carrier tape.

The detector 252 is configured to receive the reflected light from the side of the carrier tape and to generate a signal indicative of the reflected light. In some implementations, the detector 252 generates an HSV (Hue, Saturation, Value) parameter of the reflected light. For example, if the color of the reflected light is pure white, its corresponding RGB value is (255,255,255) and its corresponding HSV value is (0°, 0%, 100%). If the color is pure red, its corresponding RGB value is (255, 0, 0) and its corresponding HSV value is (0°, 100%, 100%). If the color is pure blue, its corresponding RGB value is (0, 0, 255) and its corresponding HSV value is (240°, 100%, 100%). Thus, the HSV value generated by the detector 252 corresponds to the color of the reflected light from the side of the carrier tape, which also corresponds to the color of the side of the carrier tape. The color of the side of the carrier tape can be determined based on the HSV values generated by the detector 252. In some implementations, the detector 252 generates a RGB signal to indicate the reflected light. The RGB signal can be processed in a control computer, e.g., to a corresponding HSV value to indicate the reflected light. In some examples, the detector 252 is a CCD matrix array, e.g., product No. TCS34725FNCT from AMS-TAOS USA Inc., Texas.

The signal generated by detector 252 can be read and/or processed locally, e.g., by a microprocessor. The electronic board 244 can include a communications port 256, e.g., an RS-232 serial port or a USB (universal serial bus) port, that communicates the signal and/or the processed data to a controller, e.g., the controller 156 of FIG. 1B. The controller can further communicate the signal and/or the processed data to a control computer, e.g., the computing device 112 of FIG. 1A.

The control computer can include a processor including executable instructions to receive the signal and/or the processed data and verify a polarity of components held by the tape as a function of the received signal and/or processed data. In some examples, the processor is configured to verify the polarity by comparing the received signal, e.g., the HSV value of the reflected light from the side of the tape, to a reference value associated with an expected signal corresponding to a correct component polarity.

In a representative example, cathode ends of electronic components are attached to a red carrier tape which is detected by the tape color sensor 250. The reference can include an HSV value (0°, 100%, 100%) associated with an expected red light corresponding to a cathode end of the component. If the HSV value transmitted from detector 252 matches the reference, e.g., within a predetermined threshold such as 10% difference, the processor determines that the polarity of the electronic components is correct and the machine continues running If the processor determines that a difference between the HSV value transmitted from detector 252 and the reference is above the predetermined threshold, the processor determines that the polarity of the electronic components is incorrect. In response, the processor can send an alert signal, e.g., to a machine operator, or activate an alert system, e.g., the alert system 114 of FIG. 1A. The alert system can send an alert signal to the machine operator, e.g., by activating an audible or visual alarm, displaying an alert signal on a display screen of the computing device, or perhaps even de-energizing the machine. The alert signal can notify the operator to scan a barcode of the electronic components to check the characteristics of the components.

In some implementations, as illustrated in FIG. 5C, the sensing mechanism 240 includes a second tape color sensor 260. The second tape color sensor 260 can also include a light source 261 and a detector 262. The second tape color sensor 260 can be integrated in a second electronic board 246 (also see FIG. 5A). The electronic board 244 and the second electronic board 246 can be electrically coupled and positioned on opposite sides of a gap 243 through which carrier tape 230 passes, such that the tape color sensor 250 and the second tape color sensor 260 are positioned on opposite sides of the gap 243 and configured to generate separate signals corresponding to the color of opposite sides of the tape. The separate signals corresponding to the color of opposite sides of the tape can be both transmitted to the processor of the control machine. The processor can compare the separate signals to a reference associated with an expected signal, respectively. In such a way, the color of opposite sides of the tape can be both determined and used to verify a polarity of components held by the tape. For example, the color tape may be colored on only one side of the tape, and verifying color of both sides of the tape with the tape color sensors 250 and 260 can ensure to capture the color of the tape.

In some implementations, the detector 252 is used to detect whether the tape is present or not. For example, the light source 261 on the second electronic board 246 is turned on and the light source 251 on the electronic board 242 is turned off If the tape color sensor 250 on the electronic board 242 detects the light from the light source 261, the processor can determine that there is no tape between the electronic boards 242 and 246.

Light from the light source 251 of the tape color sensor 250 may be reflected or transmitted into the detector 262 of the second tape color sensor 260, or light from the light source 261 of the second tape color sensor 260 may be reflected or transmitted into the detector 252 of the tape color sensor 250. In some implementations, a black tape is attached to the opposite side of each of light sources 251 and 261 so that light from electronic board 244 cannot be reflected back from second electronic board 246 and light from second electronic board 246 cannot be reflected back from electronic board 244.

As noted above, the sensing mechanism 240 can include a splice sensor 254 configured to be responsive to a splice connector connecting two sequential lengths of tape. The splice sensor 254 can be integrated in the electronic board 244, together with the tape color sensor 250, and positioned adjacent a side of the carrier tape. The splice sensor 254 can include a sensing element that is responsive to a particular property associated with the splicing material. For example, if the splice connector is a colored adhesive tape, the splice sensor 254 can be an optical sensor configured to be responsive to a change in color associated with the adhesive tape. If the splice connector is a metal splice connector, the splice sensor 254 can be a proximity sensor configured to be responsive to a change in magnetic property associated with the metal splice connector. In a particular example, the proximity sensor includes LDC1000NHRT sensor chip from Texas Instrument, Inc., Texas.

When the splice sensor 254 detects the splice connector on the carrier tape 230, the splice sensor 254 generates a signal indicating the detection of the splice connector. The signal is communicated to the processor of the control machine, along with the signal from the tape color sensor 250. The processor processes the signal from the splice sensor 254 and determines data associated with the connected tape or reel, e.g., component count used or remaining in the connected tape, or reel count used or remaining in the connected reel. In some examples, if the processor determines that the signal from the splice detector is received at a time not associated with a tape position corresponding to a previously noted splice connector, the processor alerts the operator, e.g., by activating the alert system.

In some examples, if the splice detector 254 detects a splice connector between a first length of tape and a second length of tape, identification data associated with each length of tape stored in a database of the control computer may be read out by the processor and subsequently compared to each other. If the data agree in a predetermined manner, which provides insurance that the spliced second length of tape is correct for a particular application, the data associated with the second length of tape may be released for use by a placement machine and processing of the second length of tape may be allowed to proceed. If a lack of agreement is found, this lack of agreement may be signaled to the operator as a warning and further processing of the second tape may be suspended. In this way, reloading correct components can be ensured without reducing production efficiency.

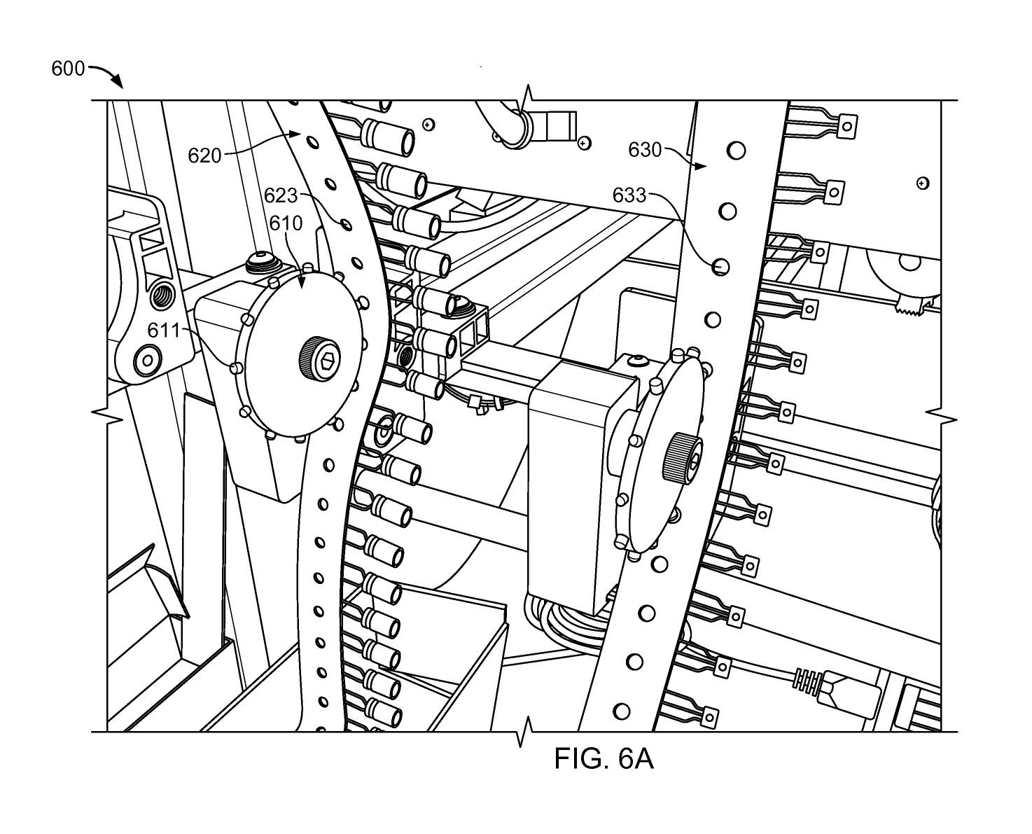

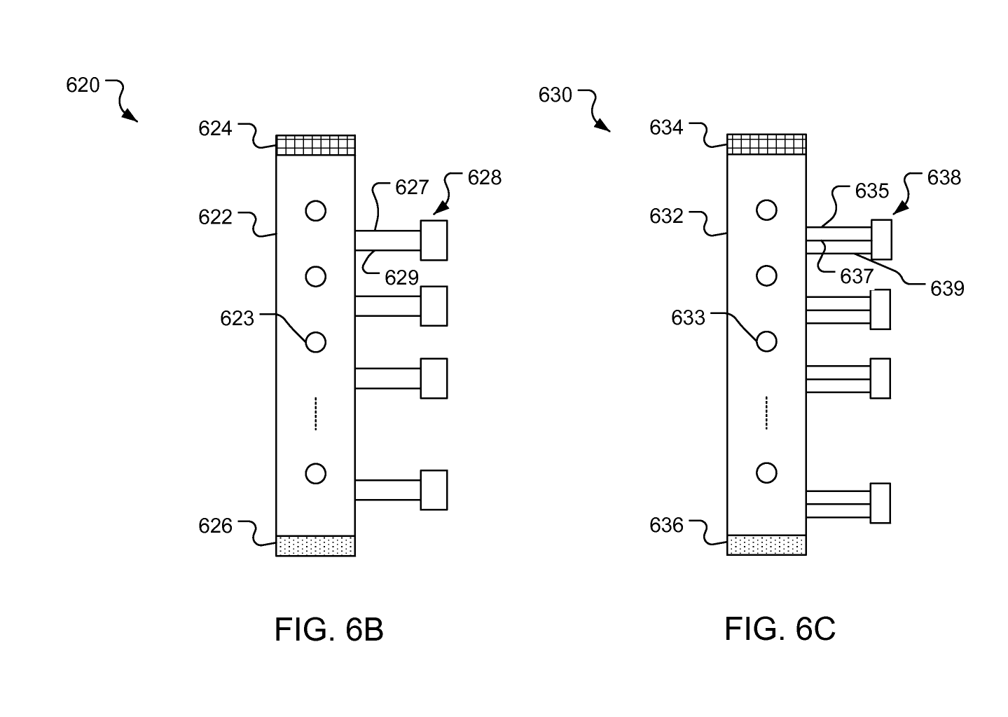

As another example electronic component placement machine, FIG. 6A shows a schematic diagram of an example radial-lead component sequencing and insertion machine 600. Machine 600 includes a series of dispensers 610 rotatable to dispense corresponding tape mounted radial-lead components 620 and 630 to an insertion mechanism (not shown). Each dispenser 610 comprises a sprocket wheel with a serial of knobs 612 protruding radially from a perimeter of the wheel and aligning with holes 623 in the tape.

FIG. 6B is a schematic view of the carrier tape 620 with two-pin radial-lead components 628. Each component 628 includes two pins 627 and 629 sequentially attached to a same carrier tape 622. The pins 627 and 629 have different polarity and are attached to the tape 622 with an order. For example, pin 627 can be positioned higher than pin 629. Thus a polarity of the component 628 can be determined by determining the order of the two pins 627 and 629. The carrier tape 620 defines a series of holes 623 that cooperate with the knobs of the dispenser to drive the tape. In this example, each component 628 is positioned between two sequential holes 623.

In some implementations, a front side 624 and a back side 626 of the tape 622 have different colors. For example, a masking tape can be applied to the back side 626 of the tape 622 to hold components 628 in place. The masking tape can be selected to have a given color, depending on the application or the polarity or identity of the retained components. A tape color sensor, e.g., the tape color sensor 250 of FIGS. 5A-5B, can be positioned at an expected location of the back side 626 of the tape 622. The tape is thread into the dispenser such that the color sensor can detect the color of the tape 622. If the processor determines that the detected color matches an expected color of the masking tape, the processor concludes that the tape is placed onto the placement machine in the correct orientation and with the correct components. In this way the processor can detect, for example, that the wrong end of the tape has been threaded first into the dispenser, resulting in the reversal of the order of pins 627 and 629 as the components are fed into the machine.

FIG. 6C is a schematic view of the carrier tape 630 with three-pin radial-lead components 638. Each component 638 includes three pins 635, 637 and 639 attached to a carrier tape 632. The pins 635, 637 and 639 have different polarity and are attached to the tape 632 with an order. For example, pin 635 can be positioned higher than pins 637 and 639. A polarity of the component 638 can be determined by verifying the order of the pins. Similar to carrier tape 620, a front side 634 and a back side 636 of the carrier tape 630 have different colors. By determining the color of a masking tape on the back side 636 by a tape color sensor, the processor can determine whether the tape is placed onto the placement machine in the correct orientation and with correct components. In this way, the processor can detect, for example, that the wrong end of the tape has been threaded first into the dispenser, resulting in the reversal of the order of the pins as the components are fed into the machine.

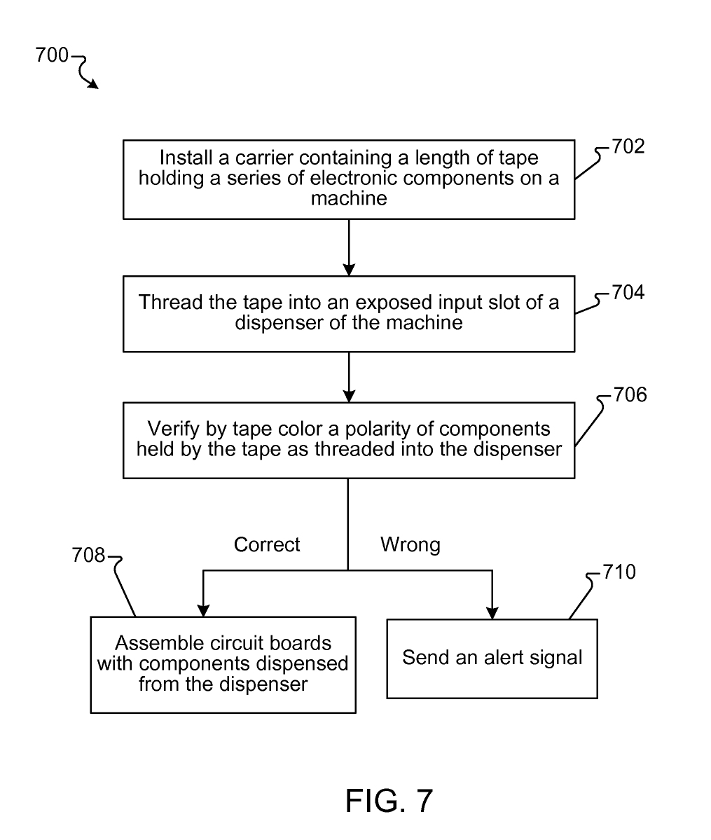

FIG. 7 shows a flowchart of an example process 700 that can be performed by an electronic component placement machine, e.g., machine 100 of FIG. 1A. The machine can be a circuit board assembly machine, e.g., an axial-lead sequencing and insertion machine.

A carrier containing a length of tape holding a series of electronic components is installed on the machine (702). The electronic components are attached in spaced relation along the tape. The electronic components can be axial-lead components with two leads attached to two parallel carrier tapes that have different colors.

The tape is threaded into an exposed input slot of a component dispenser of the machine (704). The component dispenser includes a tape color sensor downstream of the input slot. In some examples, the component dispenser includes a removable bracket mounted to a frame of the component dispenser, defining the input slot and configured to hold the tape color sensor. In some examples, the component dispenser includes two additional input slots aligned across a gap and spaced to receive parallel tapes holding opposite ends of the electronic components.

The machine verifies by tape color a polarity of components held by the tape as threaded into the component dispenser (706). The tape color sensor is configured to direct a light toward a side of the tape downstream from the exposed input slot and generate a signal indicative of a reflection of the directed light. In some examples, the signal includes an HSV value corresponding to color of the reflection of the directed light, which corresponds to the color of the side of the tape. In some implementations, the dispenser includes two tape color sensors positioned on opposite sides of a gap through which the tape passes and are configured to generate separate signals corresponding to color of opposite sides of the tape. In some examples, the two tape color sensors are integrated into two separate electronic boards that are positioned on opposite sides of the gap and electrically coupled.

The signal from the tape color sensor can be communicated to a processor of a control computer of the machine, e.g., the processor 160 of FIG. 1B. The processor can include executable instructions to receive the signal from the tape color sensor and to verify a polarity of components held by the tape as a function of the received signal. In some examples, the processor is configured to verify the polarity by comparing the received signal to a reference associated with an expected signal corresponding to a correct component polarity. For example, a correct polarity of the components should have cathode ends of the components attached to a red carrier tape. If the received signal from the tape color sensor includes an HSV value corresponding to an HSV value of pure red, i.e., (0°, 100%, 100%), the processor can determine that the polarity of the components is correct. If a difference between the received signal and the reference is above a predetermined threshold, the processor can determine that the polarity of the components is wrong.

In responding to determining that the polarity of the components is correct, the machine continues to assemble circuit boards with the components dispensed from the dispenser (708). In responding to determining that the polarity of the components is wrong, the processor sends an alert signal to a machine operator (710).

In some implementations, the dispenser includes a splice sensor configured to be responsive to a splice connector connecting two sequential lengths of tape. The splice sensor and the tape color sensor can be both integrated into a single electronic board. In step 704, the splice sensor can monitor for splice connectors when the tape is threaded into the dispenser. In some examples, the splice connector is an adhesive tape. The splice sensor can be an optical sensor configured to be responsive to a change in color associated with the splice connector. In some examples, the splice connector is a metal splice connector. The splice sensor can be a proximity sensor configured to be responsive to a change in magnetic property associated with the metal splice connector.

The splice connector can generate a signal indicating detection of a splice connector and communicate the signal to the processor. The processor can process the signal from the splice sensor and determine data associated with the connected tape or reel. In some examples, if the processor determines that the signal from the splice detector is received at a time not associated with a tape position corresponding to a previously noted splice connector, the processor processes to step 710. If the processor determines that the signal is received at a time associated with the tape position, the processor processes to step 708.

While a number of examples have been described for illustration purposes, the foregoing description is not intended to limit the scope of the invention, which is defined by the scope of the appended claims. There are and will be other examples and modifications within the scope of the following claims.

What is claimed is:

1. An electronic component sequencing and insertion machine, comprising:
a set of component tape carrier holders each configured to receive a respective carrier containing a length of tape holding leads of a series of electronic components in spaced relation along the tape; and
a set of component dispensers for sequentially dispensing individual electronic components for insertion into a printed circuit board, each component dispenser arranged to receive a corresponding tape from a corresponding one of the tape carrier holders, each component dispenser having an exposed input slot for threading a free end of the tape into the component dispenser at machine setup;
wherein each component dispenser comprises a tape color sensor downstream of the input slot, for verifying by tape color a polarity of components held by the tape as threaded into the component dispenser.

2. The machine of claim 1, wherein the tape color sensor is configured to:
direct a light toward a side of the tape downstream from the input slot; and
generate a signal indicative of a reflection of the directed light.

3. The machine of claim 1, further comprising a processor coupled to the tape color sensor, the processor including executable instructions to receive a signal from the tape color sensor, and to verify a polarity of components held by the tape as a function of the received signal.

4. The machine of claim 3, wherein the processor is configured to verify the polarity by comparing the received signal to a reference associated with an expected signal corresponding to a correct component polarity.

5. The machine of claim 4, wherein the processor is further configured to send an alert signal in response to determining that a difference between the received signal and the reference is above a predetermined threshold.

6. The machine of claim 1, wherein:
the tape color sensor is a first tape color sensor;
each component dispenser further comprises a second tape color sensor; and
the first and second tape color sensors are positioned on opposite sides of a gap through which the tape passes and are configured to generate separate signals corresponding to color of opposite sides of the tape.

7. The machine of claim 6, wherein the first tape color sensor is integrated into a first electronic board and the second tape color sensor is integrated into a second electronic board, the first and second electronic boards positioned on opposite sides of the gap and electrically coupled.

8. The machine of claim 1, wherein each component dispenser comprises a removable bracket mounted to a frame of the component dispenser, defining the input slot and configured to hold the tape color sensor.

9. The machine of claim 1, wherein each component dispenser comprises two input slots aligned across a gap and spaced to receive parallel tapes holding opposite ends of electronic components.

10. The machine of claim 1, wherein each component dispenser further comprises a splice sensor responsive to a splice connector connecting two sequential lengths of tape.

11. The machine of claim 10, wherein the splice sensor and tape color sensor are both integrated into a single electronic board.

12. The machine of claim 10, wherein the splice sensor is coupled to a processor configured to receive a signal from the splice sensor indicating detection of a splice connector.

13. The machine of claim 12, wherein the processor is further configured to alert an operator in response to receiving the signal from the splice detector at a time not associated with a tape position corresponding to a previously noted splice.

14. The machine of claim 10, wherein the splice sensor is responsive to metal splice connectors.

15. The machine of claim 10, wherein the splice sensor is responsive to a change in color associated with a splice connection.

16. A method of placing electronic components, the method comprising:
installing on a circuit board assembly machine a carrier containing a length of tape holding a series of axial lead electronic components in spaced relation along the tape;
threading the tape into an exposed input slot of a component dispenser of the machine, the component dispenser comprising a tape color sensor downstream of the input slot; and
running the machine to assemble circuit boards with components dispensed from the component dispenser, while the machine verifies by tape color a polarity of components held by the tape as threaded into the component dispenser.

17. The method of claim 16, wherein the component dispenser further comprises a splice sensor responsive to a splice connector connecting two sequential lengths of tape, and wherein running the machine comprises running the machine while the machine monitors for splice connectors at the component dispenser.
